(19) United States
(12) Patent Application Publication
(10) Pub. No.: US 2012/0013019 A1
(43) Pub. Date: Jan. 19, 2012

(54) SEMICONDUCTOR DEVICE

(75) Inventors: Takehiko SAKAMOTO, Kanagawa (JP); Yasutaka NAKASHIBA, Kanagawa (JP)

(73) Assignee: RENESAS ELECTRONICS CORPORATION, Kanagawa (JP)

(21) Appl. No.: 13/181,246

(22) Filed: Jul. 12, 2011

(30) Foreign Application Priority Data
Jul. 13, 2010 (JP) 2010-159183
Mar. 7, 2011 (JP) 2011-48819

(51) Int. Cl. H01L 23/48

(52) U.S. Cl. 257/774; 257/E23.011

(57) ABSTRACT

A signal line is formed in the a-th layer (a≧2) of a multi-layered interconnect layer and a redistribution layer. A plain line is formed in the b-th layer (b<a) of the multi-layered interconnect layer and the redistribution layer and overlaps with the signal line when seen in a plan view. Two coplanar lines that are formed in the c-th layer (b≦c≦a) of the multi-layered interconnect layer and the redistribution layer, extend in parallel to the signal line when seen in a plan view, and interpose the signal line therebetween. A distance h from the signal line to the plain line is smaller than a distance w from the signal line to the coplanar lines. A power supply line, a ground line, and another signal line are not located within the range of the height equal to the distance w from the signal line above the signal line.

This application is based on Japanese Patent Application Nos. 2010-159183 and 2011-48819, the contents of which are incorporated hereinto by reference.

### BACKGROUND

1. Technical Field

The present invention relates to a semiconductor device including a transmission line constructed by using a multi-layered interconnect layer.

2. Related Art

With the recent increase in the processing speed of semiconductor devices, the frequency of a signal propagating in the semiconductor devices has been raised. A transmission line needs to be used to transmit a signal at a high frequency.

For example, PCT International Publication No. 98/47331 discloses a interconnect board in which two conductor layers are vertically arranged above and below a signal line through which a signal is transmitted and the side surfaces of the signal line are surrounded with shield patterns and conductive pillars.

Japanese Unexamined Patent Publication No. 2008-311482 discloses a stacked device in which grooves are formed in a top surface of a lower substrate and a bottom surface of an upper substrate, and the grooves are disposed to face each other to form a space, and a signal line extends into the space.

Japanese Unexamined Patent Publication No. H10-326783 discloses a transmission line having a microstrip structure in which conductor loss can be reduced without increasing a conductor width by forming unevenness on a surface of a signal line facing a grounding conductor.

### SUMMARY

When a transmission line is assembled into a semiconductor chip, the transmission line is formed by using interconnect lines in the semiconductor chip. The interconnect lines of the semiconductor chip are often formed using a damascene method. A redistribution layer of the semiconductor chip is often formed using a plating method. As the inventor's research result, it has been proved that micro unevenness is formed on the top surface of a interconnect line even by using either the damascene method or the plating method, thereby deteriorating the transmission characteristic of the transmission line. In order to assemble the transmission line into the semiconductor chip, it is necessary to suppress the deterioration of the transmission characteristic.

In one embodiment, there is provided a semiconductor device including: a substrate; a transistor that is formed on the substrate; a plurality of interconnect layers that are formed on the substrate and the transistor and in which three or more layers overlap with each other; a first signal line that is formed in the a-th layer (a≧2) of the plurality of interconnect layers; a plain line that is formed in the b-th layer (b<a) of the plurality of interconnect layers and that overlaps with the first signal line when seen in a plan view; and two coplanar lines that are formed in the c-th layer (b≦c≦a) of the plurality of interconnect layers, that extend in parallel to the first signal line when seen in a plan view, and that interpose the first signal line therebetween. A distance h from the first signal line to the plain line is smaller than a distance w from the first signal line to the coplanar lines. A power supply line, a ground line, and another signal line are not located within the range of the height equal to the distance w from the first signal line above the first signal line.

According to the invention, the distance h from the first signal line to the plain line is smaller than the distance w from the first signal line to the coplanar line. Within the range of the height equal to the distance w from the first signal line above the first signal line, a power supply line, a ground line, and another signal line are not located. Accordingly, the side surface and the bottom surface rather than the top surface of the first signal line contribute to the transmission of a signal. As a result, even when micro unevenness is formed on the top surface of the first signal line, it is possible to suppress the transmission characteristic of a transmission line from deteriorating.

According to the invention, even when micro unevenness is formed on the top surface of a first signal line, it is possible to suppress the transmission characteristic of a transmission line from deteriorating.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a sectional view illustrating the configuration of a semiconductor device according to a first embodiment of the invention;

FIG. 2 is a sectional view illustrating the configuration of a semiconductor device according to a second embodiment of the invention;

FIG. 3 is a sectional view illustrating the configuration of a semiconductor device according to a third embodiment of the invention;

FIG. 4 is a sectional view illustrating the configuration of the semiconductor device according to invention modified example shown in FIG. 3;

FIG. 5 is a sectional view illustrating the configuration of a semiconductor device according to a fourth embodiment of the invention;

FIG. 6 is a sectional view illustrating the configuration of a semiconductor device according to a fifth embodiment of the invention;

FIG. 7 is a sectional view illustrating the configuration of a semiconductor device according to a sixth embodiment of the invention;

FIG. 8 is a sectional view illustrating the configuration of a semiconductor device according to a seventh embodiment of the invention;

FIG. 9 is a sectional view illustrating the configuration of a semiconductor device according to an eighth embodiment of the invention;

FIG. 10 is a sectional view illustrating the configuration of a semiconductor device according to a ninth embodiment of the invention;

FIG. 11 is a sectional view illustrating the configuration of a semiconductor device according to a tenth embodiment of the invention;

FIG. 12 is a sectional view illustrating the configuration of a semiconductor device according to an eleventh embodiment of the invention;

FIGS. 13A and 13B are plan views illustrating the configuration of a plain line;

FIG. 14 is a plan view of FIG. 1; and

FIG. 15 is a diagram illustrating an example of a circuit using a signal line.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, embodiments of the invention will be described with reference to the accompanying drawings. In the drawings, like elements are referenced by like reference numerals and signs and description thereof will not be repeated.

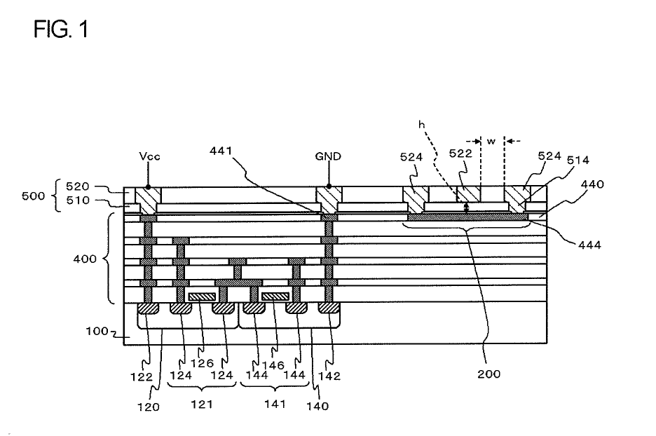

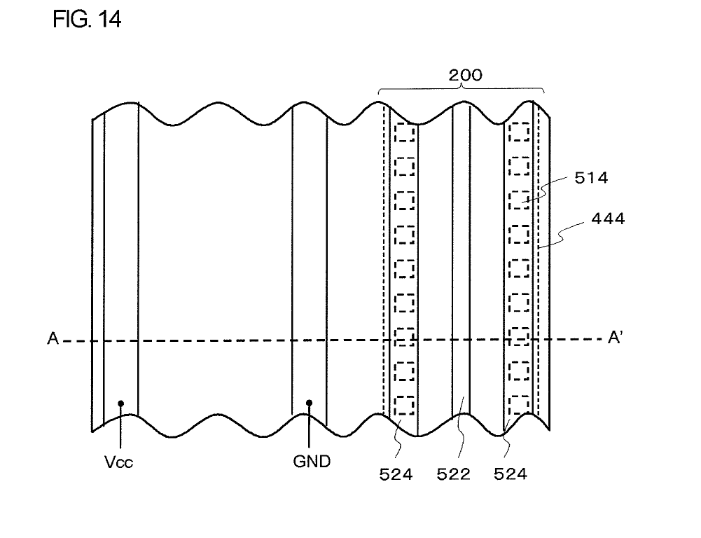

FIG. 1 is a sectional view illustrating the configuration of a semiconductor device according to a first embodiment of the invention. FIG. 14 is an example of a plan view of the semiconductor device shown in FIG. 1. This semiconductor device includes a substrate 100, a first transistor 121, a second transistor 141, a multi-layered interconnect layer 400, a redistribution layer 500, a signal line 522 (the first signal line), a plain line 444, and two coplanar lines 524. The multi-layered interconnect layer 400 and the redistribution layer 500 include three or more interconnect layers in total. The signal line 522 is formed in the a-th layer (a≧2) of the multi-layered interconnect layer 400 and the redistribution layer 500. The plain line 444 is a interconnect line serving as a return path of the signal line 522, is formed in the b-th layer (b<a) of the multi-layered interconnect layer 400 and the redistribution layer 500, and overlaps with the signal line 522 when seen in a plan view. The two coplanar lines 524 are interconnect lines serving as a return path of the signal line 522 and are formed in the c-th layer (b≦c≦a) of the multi-layered interconnect layer 400 and the redistribution layer 500. As shown in FIG. 14, the coplanar lines 524 extend in parallel to the signal line 522 when seen in a plan view and interpose the signal line 522 therebetween. As shown in FIG. 1, the distance h from the signal line 522 to the plain line 444 is smaller than the distance w from the signal line 522 to the coplanar lines 524. Here, the distance w is, for example, equal to or greater than 2 μm and equal to or less than 8 μm. A power supply line, a ground line, and another signal line are not located within the range of the height equal to w from the signal line 522 above the signal line 522. A transmission line 200 is constituted by the signal line 522, the plain line 444, and the two coplanar lines 524. The transmission line 200 is used, for example, to connect electronic elements in the semiconductor device. In FIG. 1, an example in which the coplanar lines 524 extend in parallel to the signal line 522 when seen in a plan view is shown. However, when it does not matter that the characteristic impedance of the signal line 522 slightly varies, the coplanar lines 524 may not necessarily be parallel to the signal line 522. For example, the coplanar lines 524 may be separated from the signal line 522 by equal to or greater than a predetermined distance (for example, the distance h).

In the example shown in the drawing, the signal line 522 and the coplanar lines 524 are formed in the uppermost interconnect line, that is, the redistribution line 500. That is, the signal line 522 and the coplanar line 524 are formed in the same layer (c=a). Above the signal line 522, a power supply line, a ground line, and another signal line are not located. The signal line 522 has a width greater than a height.

A power supply line Vcc and a ground line GND are disposed in an upper layer 520 of the redistribution layer 500. As shown in FIG. 14, at least a part of the transmission line including the coplanar lines 524 and the signal line 522 extends in parallel to the power supply line Vcc and the ground line GND. Here, the transmission line does not have to extend in parallel to the power supply line Vcc and the ground line GND.

The plain line 444 is formed in the uppermost interconnect layer 440 of the multi-layered interconnect layer 400. The plain line 444 is formed in a sheet shape almost over the entire area in which the signal line 522 and the coplanar lines 524 are formed when seen in a plan view. An electrode pad 441 is formed in the interconnect layer 440. A microstrip line is constituted by the signal line 522, the coplanar lines 524, and the plain line 444. The plain line 444 is generally called a ground plane. However, when it is fixed to a fixed potential, it does not necessarily have to be connected to the ground and thus it is defined as a plain line in this embodiment. The coplanar lines 524 means a transmission line generally called a coplanar waveguide in the microstrip line. The plain line 444 and the coplanar lines 524 are preferably connected to a fixed potential or both are preferably electrically connected to each other. For example, the coplanar lines 524 and the plain line 444 may be connected to a fixed potential terminal not shown in FIG. 1.

At least partially the multi-layered interconnect layer 400 has a copper line and is formed by a damascene method. In the multi-layered interconnect layer 400, the thickness of an insulating interlayer which is an insulating film located between a interconnect layer and a interconnect layer is, for example, equal to or greater than 0.1 μm and equal to or less than 10 μm and the thickness of a interconnect layer insulating film which is an insulating film forming a interconnect layer is, for example, equal to or greater than 0.1 μm and equal to or less than 10 μm. At least a part of at least one of the interconnect layer insulating film and the insulating interlayer may be formed of a low-dielectric insulating film (for example, the relative dielectric constant of which is equal to or less than 2.7) having a dielectric constant smaller than that of silicon oxide.

The redistribution layer 500 is formed on a passivation film protecting the multi-layered interconnect layer 400. The redistribution layer 500 has a configuration in which an upper layer 520 is stacked on a lower layer 510. Each layer of the redistribution layer 500 is formed of, for example, a polyimide resin layer. Vias 514 (connecting member) are buried in the lower layer 510 and the signal line 522 and the coplanar lines 524 are buried in the upper layer 520. The vias 514 connect the coplanar lines 524 to the plain line 444. In this embodiment, the vias 514 may have a dot shape when seen in a plan view or may have a groove shape extending in parallel to the coplanar lines 524.

The ground potential is applied to all of the coplanar lines 524, the vias 514, and the plain line 444. Accordingly, the ground shield of the signal line 522 is formed by the coplanar lines 524, the vias 514, and the plain line 444. A source potential may be applied to the coplanar lines 524, the vias 514, and the plain line 444.

The substrate 100 is, for example, a silicon substrate. The first transistor 121 and the second transistor 141 are a part of a logic circuit and constitute a CMOS transistor. Specifically, the first transistor 121 is of a first conductivity type and is formed in a second conductivity type of well 120. The first transistor 121 includes the first conductivity type of two impurity regions 124 serving as a source and a drain, and a gate electrode 126. The second transistor 141 is of the second conductivity type and is formed in the first conductivity type of well 140. The second transistor 141 includes the second conductivity type of two impurity regions 144 serving as a source and a drain, and a gate electrode 146. A gate insulating film (not shown) is located under each of the gate electrodes 126 and 146. These two gate insulating films have substantially the same thickness.

The second conductivity type of impurity region 122 is formed in the well 120 and the first conductivity type of impurity region 142 is formed in the well 140. A interconnect line supplying a reference potential of the first conductivity type of first transistor 121 is connected to the impurity region 122, and a interconnect line supplying a reference potential of the second conductivity type of second transistor 141 is connected to the impurity region 142.

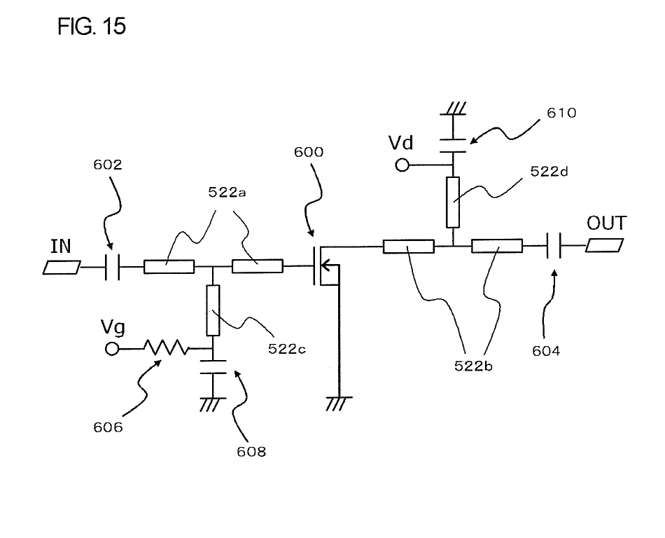

FIG. 15 shows an example of a circuit using the signal line 522. All signal lines 522a, 522b, 522c, and 522d described below are examples of the signal line 522 and accompany the coplanar lines 524. The circuit shown in the drawing is an amplification circuit amplifying an input signal and includes a signal-amplifying transistor 600. The input terminal thereof is connected to the gate electrode of the transistor 600 through a capacitor 602 and the output terminal is connected to the drain of the transistor 600 through a capacitor 604. The capacitor 602 and the gate electrode of the transistor 600 are connected to each other through the signal line 522a. The capacitor 604 and the drain of the transistor 600 are connected to each other through the signal line 522b.

A gate voltage Vg is applied to the signal line 522a through a resistor 606 and the signal line 522c. A drain voltage Vd is applied to the signal line 522b through the signal line 522d. The end of the signal line 522c opposite to the signal line 522a is grounded through a capacitor 608. The end of the signal line 522d opposite to the signal line 522b is grounded through a capacitor 610.

The operation and advantages of this embodiment will be described below. The signal line 522 is formed in the redistribution layer 500. The interconnect line of the redistribution layer 500 is formed using the plating method. The process of forming the interconnect line of the redistribution layer 500 includes a process of removing an unnecessary seed film by etching after forming the interconnect line. In this process, the top surface of the interconnect line is roughened to form micro unevenness.

According to this embodiment, the signal line 522 and the plain line 444 constitute a microstrip line, and the signal line 522 and the coplanar lines 524 constitute a coplanar line. A signal propagating in the signal line 522 mainly propagates along the rear surface of the signal line 522 when the plain line 444 is used as a return path, and mainly propagates along the side surface of the signal line 522 when the coplanar lines 524 are used as a return path. Here, as described above, since the distance h from the signal line 522 to the plain line 444 is smaller than the distance w from the signal line 522 to the coplanar line 524, the microstrip line is dominant in the transmission line 200. In addition, as described above, a power supply line, a ground line, and another signal line are not located within the range of the height equal to w from the signal line above the signal line 522. Accordingly, the ratio of a signal propagating along the surface of the signal line 522 to the signal propagating in the signal line 522 is small. Therefore, even when micro unevenness is formed on the surface of the signal line 522, it is possible to suppress the transmission characteristics of the transmission line from deteriorating. Particularly, a high-frequency signal propagating in the signal line 522 selectively propagates along the surface layer of the signal line 522 due to a surface effect. Accordingly, when micro unevenness is formed on the top surface of the signal line 522, the transmission characteristics of the high-frequency signal markedly deteriorate. In this embodiment, since the coplanar lines 524 and the plain line 444 are connected to a fixed potential, the signal selectively propagates along the surface of the signal line 522 facing the coplanar lines 524 and the plain line 444. Accordingly, the amount of signal propagating along the top surface of the signal line 522 is relatively small, thereby effectively improving the transmission characteristics of the signal propagating in the signal line 522.

The ground shield on the bottom side of the transmission line 200 is formed by the plain line 444, instead of the substrate 100. Accordingly, it is possible to suppress a high-frequency signal from leaking from the plain line 444 as the return path. As a result, it is possible to enhance the signal transmission efficiency of the transmission line 200.

Since the coplanar lines 524 are connected to the plain line 444 through the vias 514, the electrical connection therebetween is the shortest. Accordingly, even when the frequency of a signal is high, the plain line 444 and the coplanar lines 524 can be made to serve as a ground shield (return path).

By adjusting the distance h from the signal line 522 to the plain line 444 or the distance w from the signal line 522 to the coplanar lines 524, it is possible to design the transmission line 200 so that the impedance of the transmission line 200 should be a desired value (for example, 50 Ω or 75 Ω).

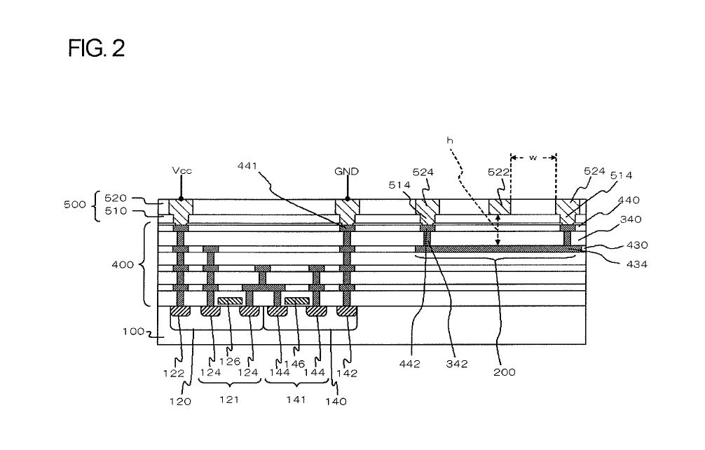

FIG. 2 is a sectional view illustrating the configuration of a semiconductor device according to a second embodiment of the invention. The semiconductor device according to this embodiment has the same configuration as the semiconductor device according to the first embodiment, except for the following.

First, a plain line 434 is provided instead of the plain line 444. The plain line 434 is formed in the second interconnect layer 430 from the uppermost of the multi-layered interconnect layer 400. The plain line 434 is connected to the coplanar lines 524 through vias 342, conductor patterns 442, and vias 514.

The vias 342 are buried in an insulating interlayer 340 located between the interconnect layer 430 and the interconnect layer 440 and the conductor patterns 442 are formed in the interconnect layer 440. The vias 342, the conductor patterns 442, and the vias 514 may be formed in a dot shape or may be formed in a shape that extends in parallel to the coplanar lines 524. In this embodiment, the distance h from the signal line 522 to the plain line 434 is smaller than the distance w from the signal line 522 to the coplanar lines 524 as well.

According to this embodiment, it is possible to achieve the same advantages as described in the first embodiment.

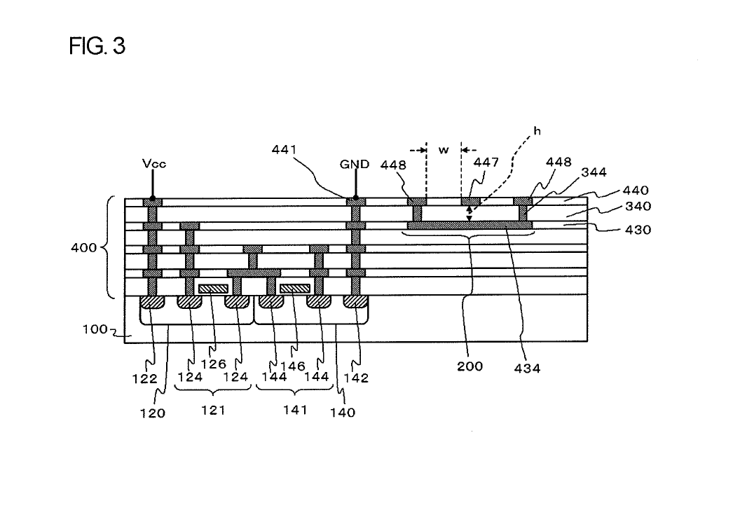

FIG. 3 is a sectional view illustrating the configuration of a semiconductor device according to a third embodiment of the invention. The semiconductor device has the same configuration as the semiconductor device according to the first embodiment, except that the transmission line 200 includes only the multi-layered interconnect layer 400.

Specifically, a signal line 447 and two coplanar lines 448 are formed in the uppermost interconnect layer 440 of the multi-layered interconnect layer 400, that is, in the same layer as the electrode pad 441. The signal line 447 and the two coplanar lines 448 are formed using the damascene method. The plain line 434 is formed in the first interconnect layer 430 below the interconnect layer 440. The two coplanar lines 448 are both connected to the plain line 434 through vias 344. The vias 344 are buried in the insulating interlayer located between the interconnect layer 440 and the interconnect layer 430.

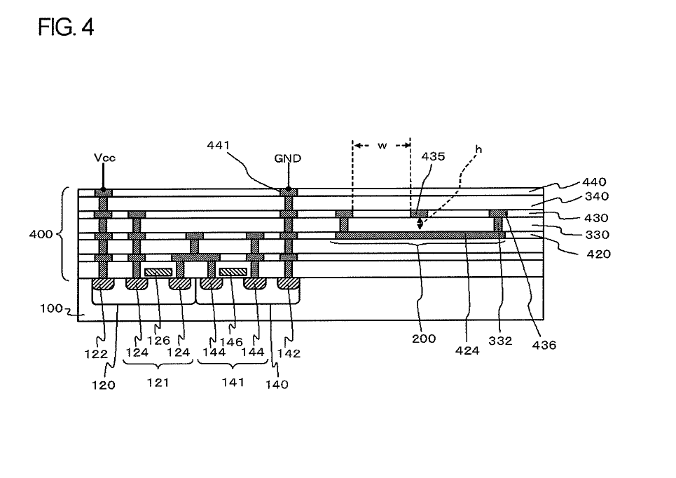

As shown in FIG. 4, the transmission line 200 may be formed using a interconnect layer other than the uppermost interconnect layer of the multi-layered interconnect layer 400. In the example shown in FIG. 4, the signal line 435 and the two coplanar lines 436 are formed in the interconnect layer 430 other than the uppermost interconnect layer of the multi-layered interconnect layer 400. The plain line 424 is formed in the first interconnect layer 420 below the interconnect layer 430. The two coplanar lines 436 are both connected to the plain line 424 through vias 332. The vias 332 are buried in the insulating interlayer 330 located between the interconnect layer 430 and the interconnect layer 420.

The operation and advantages of this embodiment will be described below. In this embodiment, the signal lines 447 and 435 are formed using the damascene method. Accordingly, micro unevenness is formed on the top surfaces of the signal lines 447 and 435 due to a chemical mechanical polishing (CMP) process of the damascene method. In this embodiment, the distance h from the signal line 435 to the plain line 424 is smaller than the distance w from the signal line 435 to the coplanar lines 436. Accordingly, the same advantages as described in the first embodiment can be achieved from this embodiment.

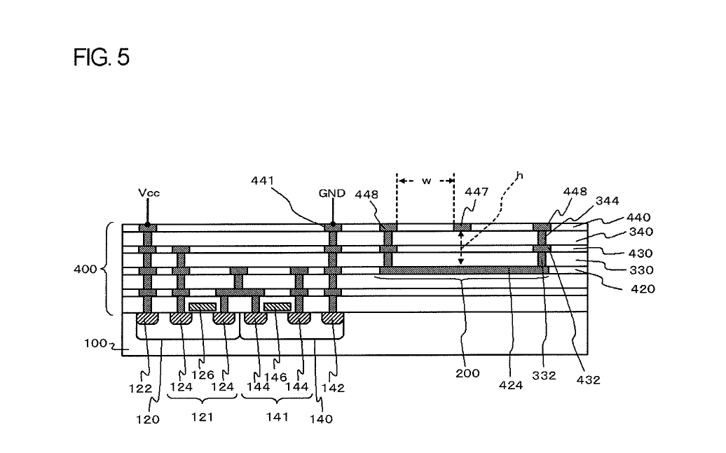

FIG. 5 is a sectional view illustrating the configuration of a semiconductor device according to a fourth embodiment of the invention. The semiconductor device according to this embodiment has the same configuration as the semiconductor device shown in FIG. 3, except that a plain line 424 is used instead of the plain line 434.

Specifically, the plain line 424 is formed in the second interconnect layer 420 below the interconnect layer 440 in which the signal line 447 is formed. Two coplanar lines 448 are both connected to the plain line 424 through vias 344, conductor patterns 432, and vias 332. The vias 344 are buried in the insulating interlayer 340 located between the interconnect layer 440 and the interconnect layer 430. The conductor patterns 432 are formed in the interconnect layer 430. The vias 332 are buried in the insulating interlayer 330 located between the interconnect layer 430 and the interconnect layer 420.

As long as the relational expression h<w is satisfied, more interconnect layers may be formed between the interconnect layer in which the signal line is formed and the interconnect layer in which the plain line is formed.

The same advantages as described in the first embodiment can be achieved from this embodiment.

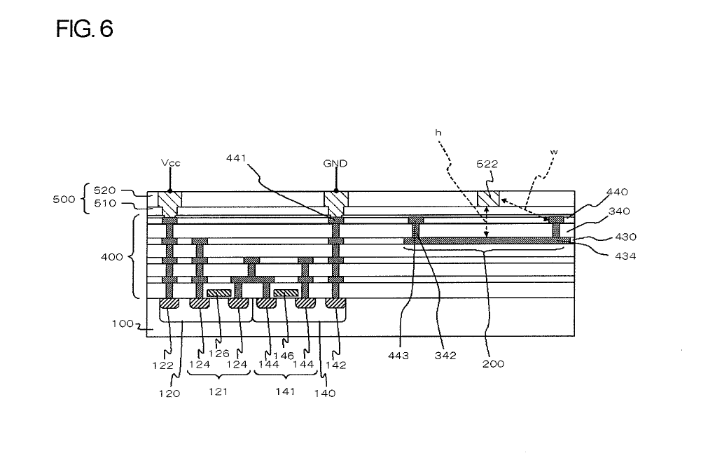

FIG. 6 is a sectional view illustrating the configuration of a semiconductor device according to a fifth embodiment of the invention. The semiconductor device according to this embodiment has the same configuration as the semiconductor device according to the second embodiment, except that the coplanar lines are formed in the uppermost interconnect layer 440 of the multi-layered interconnect layer 400 instead of the redistribution layer 500.

Specifically, the semiconductor device shown in FIG. 6 includes the coplanar lines 443 in the interconnect layer 440. That is, in this embodiment, the coplanar lines 443 are formed in the interconnect layer below the signal line 522. The coplanar lines 443 are connected to the plain line 434 through vias 342. The plain line 434 is formed in the first interconnect layer 430 below the interconnect layer 440. In this embodiment, the distance h from the signal line 522 to the plain line 434 is smaller than the distance w from the signal line 522 to the coplanar lines 443.

The same advantages as described in the second embodiment can be achieved from this embodiment.

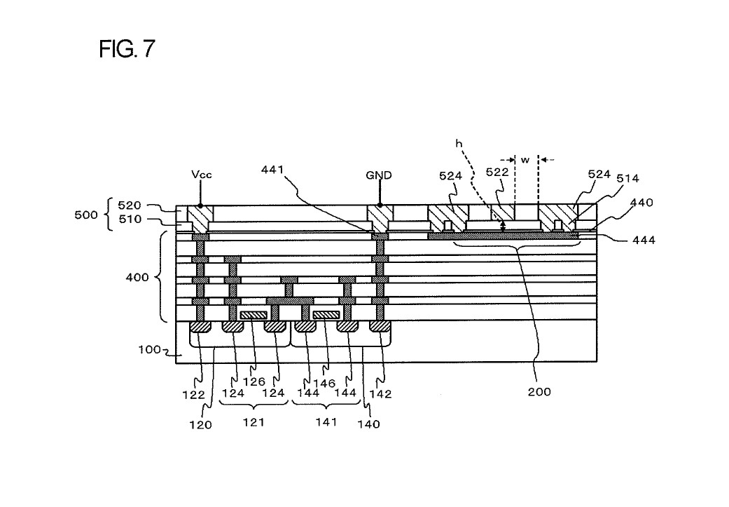

FIG. 7 is a sectional view illustrating the configuration of a semiconductor device according to a sixth embodiment of the invention. The semiconductor device according to this embodiment has the same configuration as the semiconductor device according to the first embodiment, except that plural vias 514 are formed in a single coplanar line 524 when seen in the width direction of the coplanar lines 524. In the examples shown in the drawing, two vias 514 are formed in a single coplanar line 524 when seen in the width direction thereof, but three or more vias may be formed.

The same advantages as described in the first embodiment can be achieved from this embodiment. Since plural vias 514 are formed when seen in the width direction of the coplanar lines 524, the resistance between the plain line 444 and the coplanar lines 524 can be lowered. Accordingly, it is possible to further enhance the signal transmission efficiency of the transmission line 200.

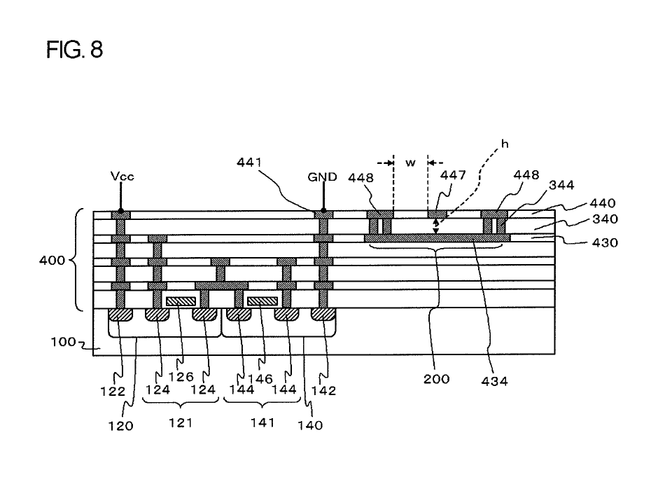

FIG. 8 is a sectional view illustrating the configuration of a semiconductor device according to a seventh embodiment of the invention. The semiconductor device according to this embodiment has the same configuration as the semiconductor device according to the third embodiment, except that plural vias 344 are formed in a single coplanar line 448 when seen in the width direction of the coplanar lines 448.

The same advantages as described in the sixth embodiment can be achieved from this embodiment.

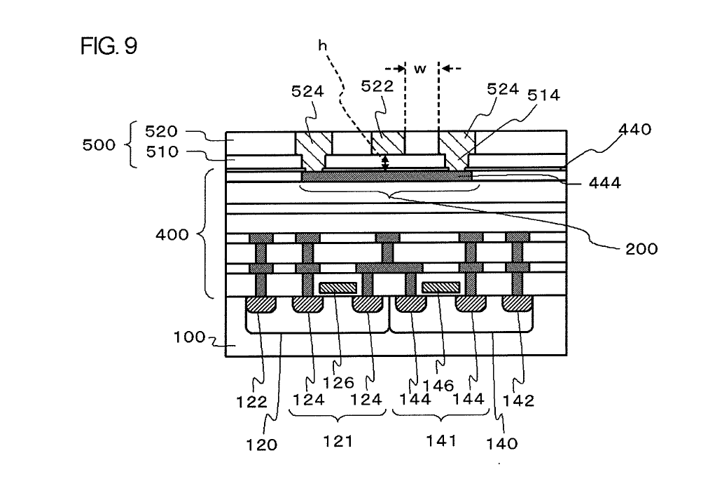

FIG. 9 is a sectional view illustrating the configuration of a semiconductor device according to an eighth embodiment of the invention. The semiconductor device according to this embodiment has the same configuration as the semiconductor device according to the first embodiment, except that at least one of the first transistor 121 and the second transistor 141 overlaps with the plain line 444 of the transmission line 200 when seen in a plan view.

The same advantages as described in the first embodiment can be achieved from this embodiment. At least one of the first transistor 121 and the second transistor 141 are disposed below the transmission line 200. Accordingly, compared with the case in which the transmission line 200 and the first and second transistors 121 and 141 are formed in different regions, it is possible to reduce the size of the semiconductor device. Since the plain line 444 is formed between the signal line 522 and the first and second transistors 121 and 141, it is possible to suppress a signal propagating in the signal line 522 from affecting the operation of the first transistor 121 and the second transistor 141. This advantage is particularly marked when the signal line 522 is surrounded with the plain line 444, the coplanar lines 524, and the vias 514, as shown in the drawing.

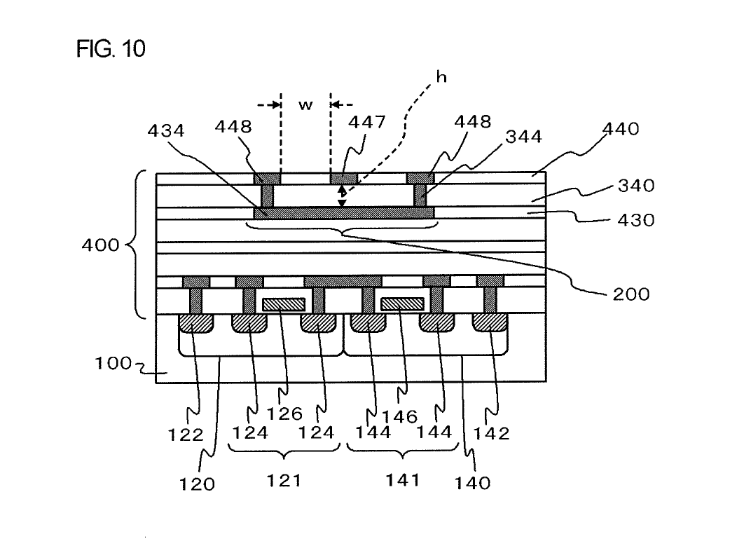

FIG. 10 is a sectional view illustrating the configuration of a semiconductor device according to a ninth embodiment of the invention. The semiconductor device according to this embodiment has the same configuration as the semiconductor device according to the third embodiment, except that at least one of the first transistor 121 and the second transistor 141 overlaps with the plain line 434 of the transmission line 200 when seen in a plan view.

The same advantages as described in the eighth embodiment can be achieved from this embodiment.

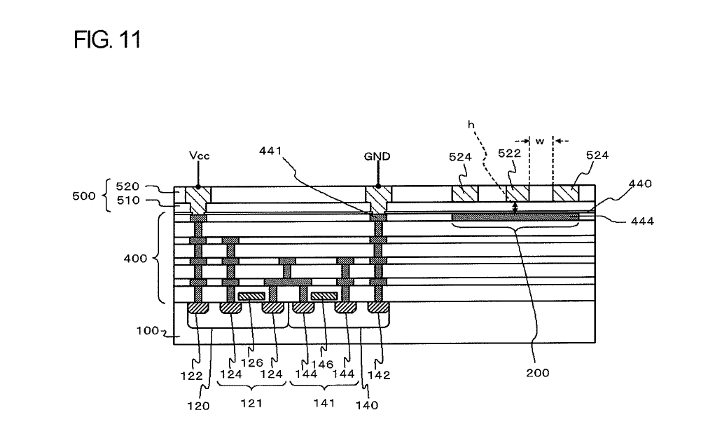

FIG. 11 is a sectional view illustrating the configuration of a semiconductor device according to a tenth embodiment of the invention. The semiconductor device according to this embodiment has the same configuration as the semiconductor device according to the first embodiment, except for the following.

First, the semiconductor device does not include the vias 514. The coplanar lines 524 may be connected to the same one of a ground line and a power supply line as the plain line 444 or may be connected to a different one.

The same advantages as described in the first embodiment can be achieved from this embodiment. Since the coplanar lines 524 may be connected to one of the ground line and the power supply line different from that of the plain line 444, it is possible to improve the degree of freedom in drawing out the interconnect lines.

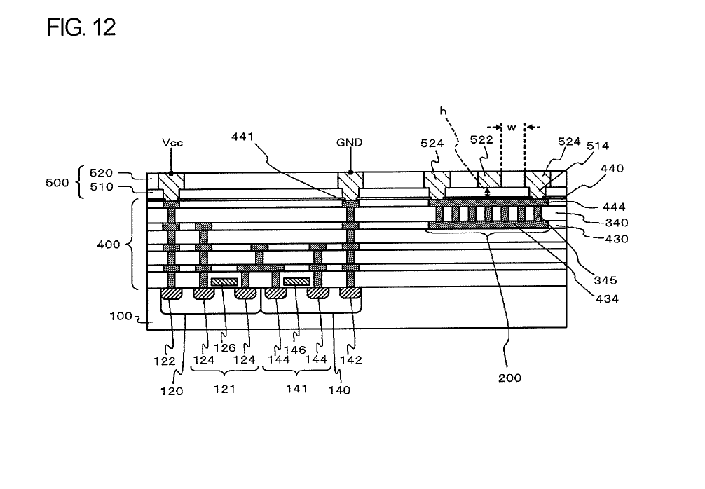

FIG. 12 is a sectional view illustrating the configuration of a semiconductor device according to an eleventh embodiment of the invention. The semiconductor device according to this embodiment has the same configuration as the semiconductor device according to the first embodiment, except for the following.

First, the plain line 434 is formed in the first interconnect layer 430 below the interconnect layer 440 in which the plain line 444 is formed. That is, in this embodiment, plural plain lines 444 and 434 are formed in different interconnect layers so as to overlap with each other when seen in a plan view. The plural plain lines 444 and 434 are connected to each other through plural vias 345.

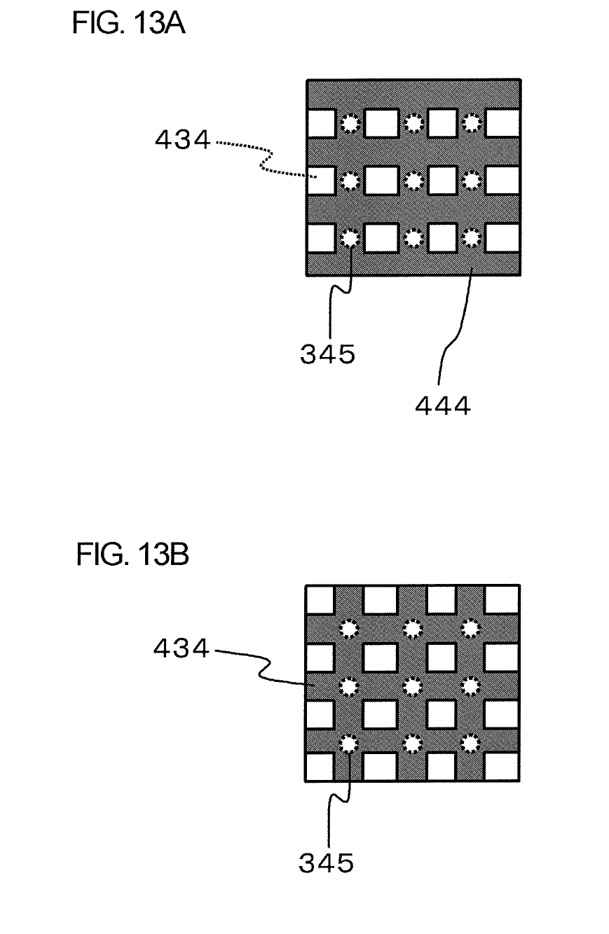

FIG. 13A is a plan view illustrating the configuration of the plain line 444 and FIG. 13B is a plan view illustrating the configuration of the plain line 434. As shown in the drawings, the plain lines 444 and 434 are formed in a mesh shape and partially overlap with each other when seen in a plan view. Particularly, in the example shown in the drawings, the plain line 434 is formed in a mesh shape so as to bury the gap of the plain line 444 when seen in a plan view. The vias 345 are disposed in portions in which the plain lines 444 and 434 overlap with each other when seen in a plan view.

Specifically, the plain lines 444 and 434 each have substantially square openings arranged in a matrix shape and have a mesh shape by arranging the openings. The openings formed in the plain line 434 and the openings formed in the plain line 444 are alternately arranged. Accordingly, when the plain lines 444 and 434 are superposed on each other and when seen in a plan view, there is no gap between the plain lines 444 and 434.

The same advantages as described in the first embodiment can be achieved from this embodiment. Since the planar shapes of the plain line 444 and 434 can be changed, the degree of adjustment of the impedance of the transmission line 200 is widened.

In this embodiment, the plain lines 444 and 434 may have a sheet shape instead of a mesh shape.

While the embodiments of the invention have been described with reference to the accompanying drawings, the embodiments are only examples of the invention and various configurations other than the embodiments may be employed.

It is apparent that the present invention is not limited to the above embodiment, and may be modified and changed without departing from the scope and spirit of the invention.

What is claimed is:

1. A semiconductor device comprising:
a substrate;
a transistor that is formed over the substrate;
a plurality of interconnect layers that are formed over the substrate and the transistor and in which three or more layers overlap with each other;
a first signal line that is formed in the a-th layer (a≧2) of the plurality of interconnect layers;
a plain line that is formed in the b-th layer (b<a) of the plurality of interconnect layers and that overlaps with the first signal line when seen in a plan view; and
two coplanar lines that are formed in the c-th layer (b≦c≦a) of the plurality of interconnect layers, that extend in parallel to the first signal line when seen in a plan view, and that interpose the first signal line therebetween,
wherein a distance h from the first signal line to the plain line is smaller than a distance w from the first signal line to the coplanar lines, and
wherein a power supply line, a ground line, and another signal line are not located within the range of the height equal to the distance w from the first signal line above the first signal line.

2. The semiconductor device according to claim 1, wherein the a-th layer is an uppermost interconnect layer of the plurality of interconnect layers.

3. The semiconductor device according to claim 2, wherein the a-th layer is a redistribution layer.

4. The semiconductor device according to claim 1, wherein the interconnect line located in the a-th layer is formed using a damascene method.

5. The semiconductor device according to claim 1, wherein the plain line and the coplanar line are connected to a fixed potential terminal.

6. The semiconductor device according to claim 1 , wherein the plain line and the coplanar line are electrically connected to each other.

7. The semiconductor device according to claim 1, wherein a relational expression c=a is satisfied.

8. The semiconductor device according to claim 1, wherein the first signal line has a width greater than a height.

9. The semiconductor device according to claim 1, wherein the distance w is equal to or greater than 2 μm and equal to or less than 8 μm.

10. The semiconductor device according to claim 1, wherein the transistor overlaps with the plain line when seen in a plan view.

11. The semiconductor device according to claim 1, wherein the coplanar lines are connected to the plain line through a connecting member formed in the interconnect layers.

12. The semiconductor device according to claim 11, wherein a plurality of the connecting members are formed when seen in the width direction of the coplanar lines.

13. The semiconductor device according to claim 1, wherein a plurality of the plain lines are formed in different interconnect layers each other so as to overlap with each other when seen in a plan view, and
wherein the plurality of plain lines are connected to each other through vias.

14. The semiconductor device according to claim 13, wherein the plurality of plain lines are formed in a mesh shape and partially overlap with each other in the vertically neighboring layers when seen in a plan view, and
wherein the vias are disposed in regions in which the vertically neighboring plain lines overlap with each other when seen in a plan view.
